(19) United States
(12) Patent Application Publication
(10) Pub. No.: US 2025/0393212 A1
(43) Pub. Date: Dec. 25, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventor: Dongseog EUN, Suwon-si (KR)

(21) Appl. No.: 19/004,638

(22) Filed: Dec. 30, 2024

(30) Foreign Application Priority Data
Jun. 19, 2024 (KR) 10-2024-0079626

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

The present disclosure provides a semiconductor device with improved electrical characteristics and reliability. The semiconductor device may include a cell substrate including a cell array region and an extension region, a mold structure including a plurality of mold insulating layers and a plurality of gate electrodes with the mold insulating layers and the gate electrodes alternately stacked with each other in a first direction on the cell substrate, a channel structure penetrating through the mold structure in the cell array region and extending in the first direction, a plurality of word line contacts connected to the plurality of gate electrodes, and a word line cutting structure separating the mold structure in the cell array region The word line cutting structure has a stepped structure that decreases in length in the first direction in the extension region at locations farther away from the cell array region in the second direction.

### CROSS-REFERENCE TO RELATED APPLICATION

This application claims priority to Korean Patent Application No. 10-2024-0079626, filed in the Korean Intellectual Property Office on Jun. 19, 2024, the entire contents of which are hereby incorporated by reference.

### BACKGROUND

### Field

The present disclosure relates to a semiconductor device and an electronic system including the same.

### Description of Related Art

There is a need for a semiconductor memory device capable of storing high-capacity data in an electronic system that requires data storage. Accordingly, ways to increase the data storage capacity of the semiconductor memory devices are being studied. For example, as one of the methods for increasing the data storage capacity of the semiconductor device, a semiconductor device has been proposed, which includes three-dimensional arrangement of memory cells instead of two-dimensional arrangement of memory cells.

### SUMMARY

In order to solve one or more problems (e.g., the problems described above and/or other problems not explicitly described herein), the present disclosure provides a semiconductor device with improved electrical characteristics and reliability.

In order to solve one or more problems (e.g., the problems described above and/or other problems not explicitly described herein), the present disclosure also provides an electronic system with improved electrical characteristics and reliability.

According to some example embodiments of the present disclosure for solving the above technical problems, a semiconductor device may include a cell substrate including a cell array region and an extension region, a mold structure including a plurality of mold insulating layers and a plurality of gate electrodes, wherein the mold insulating layers are alternately stacked with the gate electrodes on the cell substrate in a first direction perpendicular to an upper surface of the cell substrate, and the mold insulating layers and the gate electrodes extend lengthwise in a second direction parallel to the upper surface of the cell substrate, a channel structure penetrating through the mold structure in the cell array region and extending lengthwise in the first direction, a plurality of word line contacts, wherein each of the word line contacts is connected to a respective gate electrode of the plurality of gate electrodes, and a word line cutting structure separating the mold structure in the cell array region in a third direction perpendicular to each of the first and second directions, the word line cutting structure has a stepped shape that decreases in length in the first direction in the extension region as the word line cutting structure extends away from the cell array region in the second direction.

According to some example embodiments of the present disclosure for solving the above technical problems, a semiconductor device may include a peripheral circuit structure, and a cell structure stacked on the peripheral circuit structure, the cell structure includes: a cell substrate including a cell array region and an extension region, a mold structure including a plurality of mold insulating layers and a plurality of gate electrodes, wherein the mold insulating layers alternately stacked in a first direction perpendicular to an upper surface of the cell substrate with the gate electrodes on the cell substrate and the mold insulating layers extend lengthwise in a second direction parallel to the upper surface of the cell substrate, the mold structure includes a plurality of support insulating layers with each support insulating layer of the plurality of support insulating layers formed at the same vertical level as a corresponding gate electrode of the plurality of gate electrodes, a channel structure penetrating through the mold structure in the cell array region and extending lengthwise in the first direction, and a plurality of word line contacts, each of the word line contacts is connected to a corresponding gate electrode of the plurality of gate electrodes, the length in the second direction of each of the plurality of gate electrodes that are farther away from the cell substrate than a first gate electrode of the plurality of gate electrodes is less than the length in the second direction of the first gate electrode, and the length in the second direction of each of the plurality of support insulating layers that are farther away from the cell substrate than a first support insulating layer of the plurality of support insulating layers is less than the length of the first support insulating layer in the first direction.

According to some example embodiments of the present disclosure for solving the above technical problems, an electronic system may include a main substrate, on the main substrate, a semiconductor device including a peripheral circuit structure and a cell structure stacked on the peripheral circuit structure, and on the main substrate, a controller electrically connected to the semiconductor device, the cell structure includes: a cell substrate including a cell array region and an extension region, a mold structure including a plurality of mold insulating layers and a plurality of gate electrodes, the mold insulating layers are alternately stacked in a first direction perpendicular to an upper surface of the cell substrate the gate electrodes on the cell substrate, the mold structure includes a first surface facing the cell substrate and a second surface positioned opposite to the cell substrate, the mold structure including a plurality of support insulating layers with each support insulating layer of the plurality of support insulating layers formed at the same vertical level as a corresponding gate electrode of the plurality of gate electrodes, each of the plurality of gate electrodes extends in a second direction parallel to the upper surface of the cell substrate, a channel structure penetrating through the mold structure in the cell array region and extending lengthwise in the first direction, a plurality of support columns extending lengthwise in the first direction in the extension region, some of the plurality of support columns are disposed in the mold structure and support columns that are not disposed in the mold structure protrude above the mold structure, a plurality of word line contacts extending lengthwise in the first direction in the extension region, some of the word line contacts are disposed in the mold structure, and word line contacts not disposed in the mold structure protrude from the second surface of the mold structure, and a word line cutting structure penetrating through the mold structure in the first direction in the cell array region, and having a stepped shape decreasing in length in the first direction in the extension region at positions farther away from the cell array region in the second direction, the length in the second direction of each of the plurality of gate electrodes that is nearer to the second surface of the mold structures than a first gate electrode of the plurality of gate electrodes is greater than the length in the second direction of the first gate electrode, and the length in the second direction of each of the plurality of support insulating layers that is nearer to the second surface of the mold structure than a first support insulating layer of the plurality of support insulating layers is less than the length in the second direction of the first support insulating layer.

According to some aspects of the present disclosure, the word line contact, the support column, and the word line cutting structure can be formed together, thereby reducing an area of the semiconductor device and improving efficiency of manufacturing process.

### BRIEF DESCRIPTION OF THE DRAWINGS

FIG. 1 is a plan view of a semiconductor device provided to explain the semiconductor device according to some aspects.

FIG. 2 is a cross-sectional view taken along line A-A′ of FIG. 1 according to some embodiments.

FIG. 3 is a cross-sectional view taken along line B-B′ of FIG. 1 according to some embodiments.

FIG. 4 is a cross-sectional view taken along line C-C′ of FIG. 1 according to some embodiments.

FIG. 5 is a cross-sectional view taken along line D-D′ of FIG. 1 according to some embodiments.

FIG. 6 is a cross-sectional view taken along line A-A′ of FIG. 1 according to some embodiments.

FIG. 7 is a cross-sectional view taken along line C-C′ of FIG. 1 according to some embodiments.

FIG. 8 is a cross-sectional view taken along line D-D′ of FIG. 1 according to some embodiments.

FIGS. 9A to 13A, 9B to 13B, 14-15, 16A to 17A, and 16B to 17B are diagrams showing intermediate stages of a semiconductor device being manufactured, provided to explain a method for manufacturing a semiconductor device according to some aspects.

FIG. 18 is a block diagram provided as an example to explain an electronic system according to some aspects.

FIG. 19 is an example perspective view illustrating an electronic system including a semiconductor device according to some aspects.

FIG. 20 is a schematic cross-sectional view taken along line V-V of FIG. 19.

### DETAILED DESCRIPTION

Hereinafter, a semiconductor device and a method for manufacturing the same according to some aspects of the inventive concept will be described in detail with reference to the drawings in which various embodiments are shown. The inventive concept may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail.

Hereinafter, example embodiments will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

In the following description when an element is referred to as being “connected to” another element, the connection is an electrical connection, unless the context clearly indicates otherwise. An electrical connection is a physical connection in which an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

An item, layer, or portion of an item or layer described as extending “lengthwise” in a particular direction has a length in the particular direction and a width perpendicular to that direction, where the length is greater than the width.

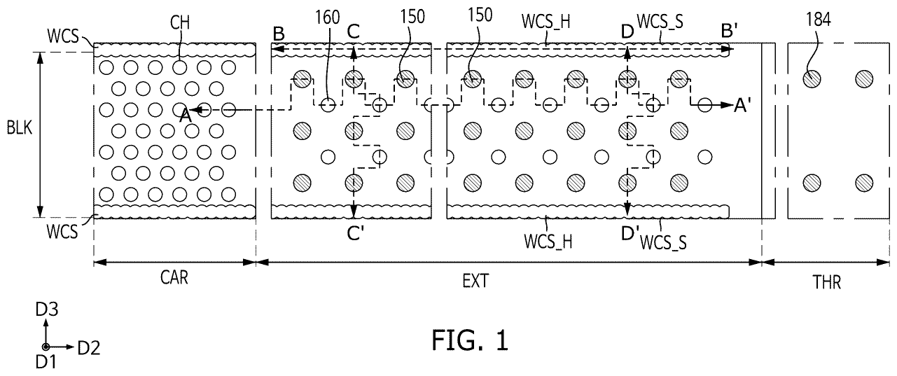

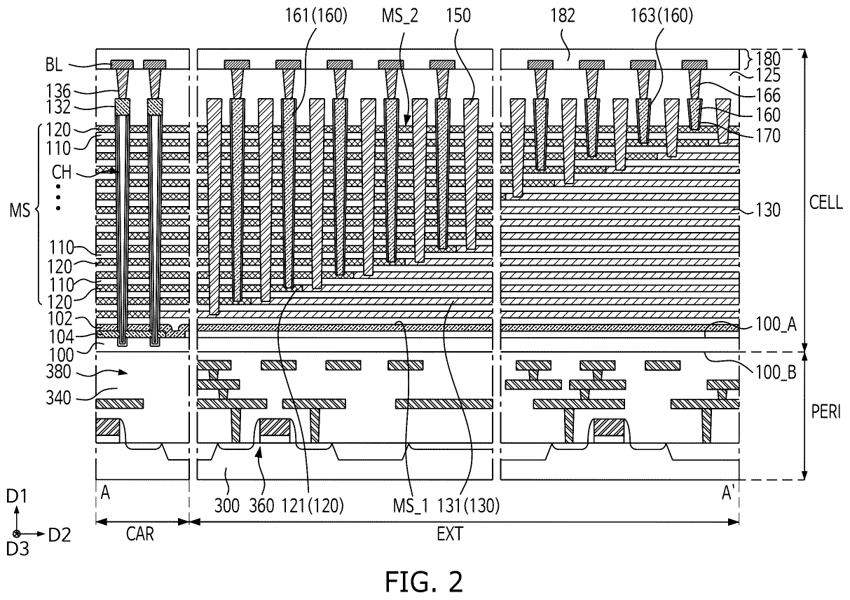

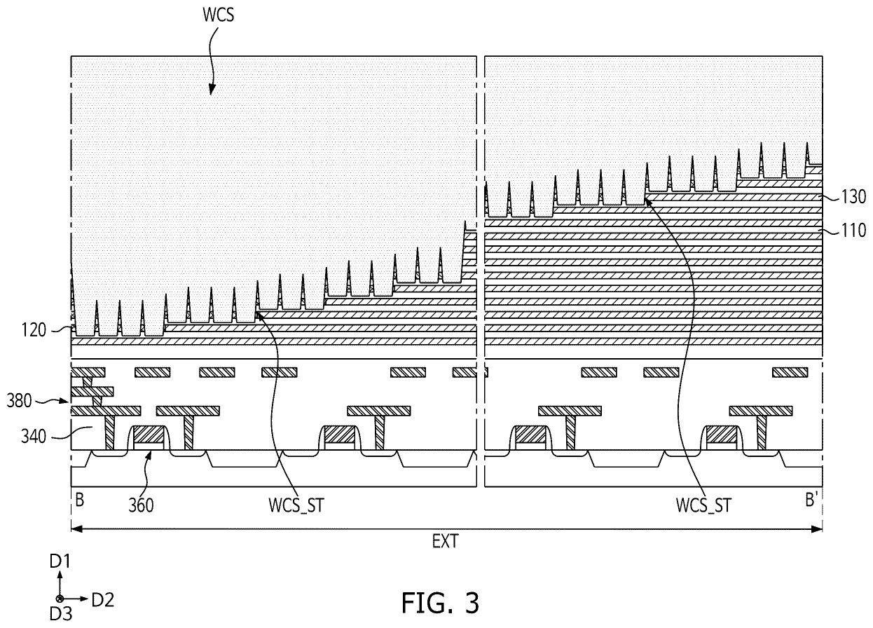

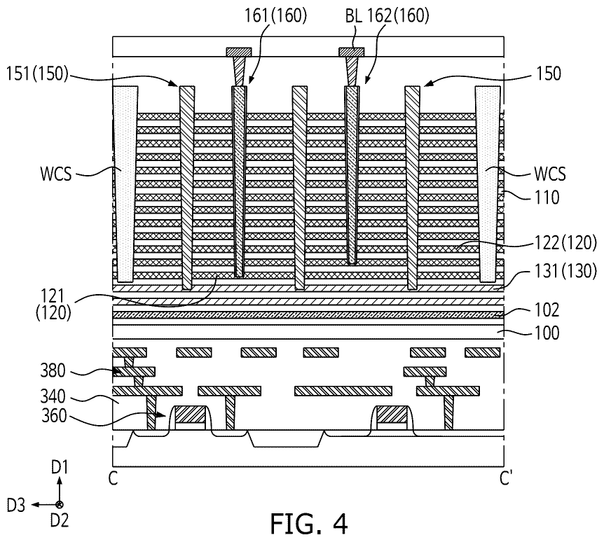

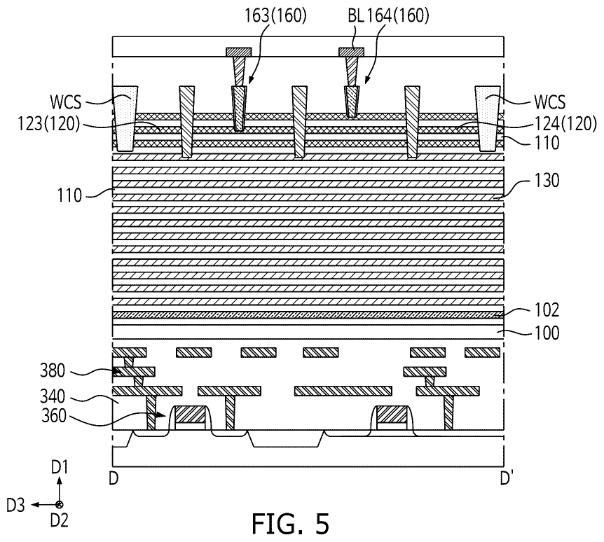

FIG. 1 is a plan view of a semiconductor device provided to explain the semiconductor device according to some aspects. FIG. 2 is a cross-sectional view taken along line A-A′ of FIG. 1 according to some embodiments. FIG. 3 is a cross-sectional view taken along line B-B′ of FIG. 1 according to some embodiments. FIG. 4 is a cross-sectional view taken along line C-C′ of FIG. 1 according to some embodiments. FIG. 5 is a cross-sectional view taken along line D-D′ of FIG. 1 according to some embodiments.

Referring to FIGS. 1 to 5, the semiconductor device according to some aspects may include a cell structure CELL and a peripheral circuit structure PERI.

The cell structure CELL may include a cell substrate 100, a first source layer 102, a second source layer 104, a mold structure MS, a channel structure CH, a bit line BL, a support column 150, a word line contact 160, a contact spacer 170, a cell wiring structure 180, a word line cutting structure WCS, etc. The first source layer 102 and the second source layer 104 may be referred to collectively as source structures 102 and 104.

The cell substrate 100 may include a cell array region CAR, an extension region EXT, and a through region THR.

A memory cell array including a plurality of memory cells may be formed on the cell array region CAR. The channel structure CH, the mold structure MS, the bit line BL, the source structures 102 and 104, etc. may be disposed on the cell array region CAR. In the present disclosure, the expression “a configuration B is formed (or disposed) on a configuration A” is not limited to the configuration B being formed or disposed in contact with the configuration A. For example, it may also include an aspect in which another configuration C is interposed between the configuration B and the configuration A. In addition, in the disclosure, the expression that “the configuration B is formed or disposed on the configuration A” is not limited to the configuration B being disposed above the configuration A in the drawings. For example, it may also include an aspect in which the configuration B is disposed below, or to the right or left side of the configuration A in the drawing.

The extension region EXT may be disposed adjacent to the cell array region CAR. The peripheral region of the cell substrate 100 may be a region that borders a lateral extent of the cell array region CAR. For example, the extension region EXT may surround the cell array region CAR in a lateral direction. The word line contact 160, the contact spacer 170, the support column 150, the mold structure MS, etc. may be disposed on the extension region EXT.

The through region THR may be disposed outside the extension region EXT (e.g., disposed laterally outward). For example, the through region THR may be disposed on an outer side of the extension region EXT and the cell array region CAR may be disposed on an inner side of the extension region EXT, but aspects are not limited thereto. A source contact 184, an input and output contact, etc. may be disposed in the through region THR.

The cell substrate 100 may be disposed on the peripheral circuit structure PERI. For example, the cell substrate 100 may include a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate, etc. In some aspects, the cell substrate 100 may include polysilicon (poly Si).

The cell substrate 100 may include a first surface 100_A and a second surface 100_B opposite to the first surface 100_A. The first surface 100_A of the cell substrate 100 may refer to a surface on which the mold structure MS and the channel structure CH are disposed. The first surface 100_A of the cell substrate 100 may refer to an upper surface of the cell substrate 100, and the second surface 100_B of the cell substrate 100 may refer to a lower surface of the cell substrate 100 as viewed in the orientation of the figures.

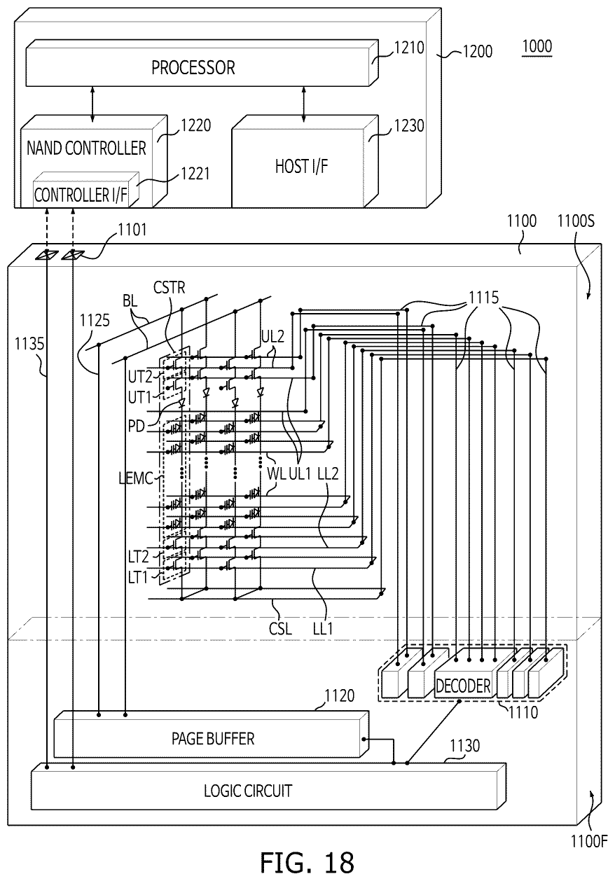

The source structures 102 and 104 may be formed on the cell substrate 100. The source structures 102 and 104 may be disposed between the cell substrate 100 and the mold structure MS. For example, the source structures 102 and 104 may extend along the first surface 100_A of the cell substrate 100. The source structures 102 and 104 may be formed to be connected to a semiconductor pattern of the channel structure CH. For example, the second source layer 104 of the source structures 102 and 104 may penetrate through an information storage film of a channel structure and contact the semiconductor pattern of the channel structure. The source structures 102 and 104 may be provided as a common source line (e.g., CSL of FIG. 18) of the semiconductor device. For example, the source structures 102 and 104 may include polysilicon or metal doped with an impurity, but aspects are not limited thereto.

In some aspects, the channel structure CH may penetrate through the source structures 102 and 104. For example, a lower portion of the channel structure CH may penetrate through the source structures 102 and 104 and extend into the cell substrate 100.

In some aspects, the source structures 102 and 104 may include multiple films or layers. For example, the source structures 102 and 104 may include the first source layer 102 and the second source layer 104 which are stacked in order on the cell substrate 100. Each of the first source layer 102 and the second source layer 104 may include polysilicon doped with an impurity or polysilicon undoped with an impurity, but aspects are not limited thereto. The first source layer 102 may be in contact with the semiconductor pattern and provided as a common source line (e.g., CSL of FIG. 18) of the semiconductor memory device. The second source layer 104 may be used as a support layer for preventing the mold stack (e.g., the mold structure MS) from collapsing or falling in a replacement process for forming the first source layer 102.

Although not illustrated, a base insulating layer may be interposed between the cell substrate 100 and the source structures 102 and 104. For example, the base insulating film may include silicon oxide, silicon nitride, or silicon oxynitride, but is not limited thereto.

The mold structure MS may be disposed on the source structures 102 and 104. The mold structure MS may be disposed on the cell array region CAR and the extension region EXT of the cell substrate 100. The mold structure MS may include a plurality of mold insulating layers 110 and a plurality of gate electrodes 120, which are alternately stacked in a first direction D1 perpendicular to the first surface 100_A of the cell substrate 100. Each of the mold insulating layers 110 and each of the gate electrodes 120 may have a layered structure extending parallel to the first surface 100_A of the cell substrate 100. The gate electrodes 120 may be sequentially stacked on the source structures 102 and 104 and spaced apart from each other by the mold insulating layers 110. The gate electrodes 120 and the mold insulating layers 110 may be sequentially stacked on the source structures 102 and 104. For convenience of description, it is illustrated herein that the plurality of mold insulating layers 110 and the plurality of gate electrodes 120 each total 15 layers, but aspects are not limited thereto. The plurality of mold insulating layers 110 and the plurality of gate electrodes 120 may extend in a second direction D2 parallel to the first surface 100_A of the cell substrate 100. The second direction D2 may be referred to as a lateral or horizontal direction with respect to the first surface 100_A of the cell substrate.

The mold structure MS may be disposed on the cell substrate 100. The mold structure MS may include a first surface MS_1 facing the cell substrate 100 and a second surface positioned opposite to the cell substrate 100. The second surface MS 2 of the mold structure MS may be positioned opposite to the first surface MS_1 of the mold structure MS. For example, the first surface MS_1 of the mold structure MS may be a lower surface of the mold structure MS, and the second surface MS_2 of the mold structure MS may be an upper surface of the mold structure MS.

In some aspects, some of the plurality of gate electrodes 120 may be provided as a ground selection line GSL of the semiconductor memory device. The other gate electrodes 120 of the plurality of gate electrodes 120 may be provided as a string selection line SSL of the semiconductor memory device. For example, the gate electrode 120, of the plurality of gate electrodes 120, adjacent to the common source plate 105 may be provided as a ground selection line GSL. The gate electrode 120, of the plurality of gate electrodes 120, adjacent to or nearest to the bit line BL may be provided as the string select line SSL. However, aspects are not limited thereto. The arrangement and number of the ground selection lines GSL and the string select lines SSL may vary.

The mold insulating layer 110 may include an insulating material. For example, the mold insulating layer 110 may include silicon oxide, silicon nitride, or silicon oxynitride, but aspects are not limited thereto.

The gate electrode 120 may include a conductive material. For example, the gate electrode 120 may include a metal such as tungsten (W), cobalt (Co), nickel (Ni), or a semiconductor material such as silicon, but aspects are not limited thereto.

The mold structure MS may include a plurality of support insulating layers 130 formed at the same vertical level as the plurality of gate electrodes 120 (e.g., a support insulating layer 130 may be in line with a respective gate electrode 120). Each support insulating layer 130 of the plurality of support insulating layers 130 may be positioned on the same layer as a respective gate electrode 120 of the plurality of gate electrodes 120. One layer of gate electrode 120 and one layer of support insulating layer 130 may together form one layer. The support insulating layers 130 of plurality of support insulating layers 130 may be alternately stacked with the mold insulating layers 110 of the plurality of mold insulating layers 110 in the first direction D1. As will be described later, the plurality of support insulating layers 130 may be remaining portions of an initial plurality of support insulating layers 130 that have not been replaced with the gate electrodes 120 when the plurality of gate electrodes 120 are formed.

The support insulating layer 130 may include an insulating material. For example, the support insulating layer 130 may include silicon oxide, silicon nitride, or silicon oxynitride, but aspects are not limited thereto.

The length in the second direction D2 of each gate electrode 120 of the plurality of gate electrodes 120 may increase as the gate electrode 120 is positioned farther away from the cell substrate 100 in the first direction D1. For example, a first gate electrode 120 may have a shorter length in the second direction D2 than a second gate electrode 120 that is closer to the first surface MS_1 of the mold structure MS, and a longer length in the second direction D2 than a third gate electrode D3 that is closer to the second surface MS_2 of the mold structure MS.

The length of the mold structure MS in the second direction D2 may be constant from the first surface MS_1 of the mold structure MS to the second surface MS_2 of the mold structure MS. For example, each of the layers forming the mold structure MS may have the same length in the second direction D2. For example, the length in the second direction D2 of the plurality of mold insulating layers 110 forming the mold structure MS may be the same as the length in the second direction D2 of the plurality of gate electrodes 120 combined with the plurality of support insulating layers 130. For example, for each layer of the mold structure, the sum of the lengths in the second direction D2 of a gate electrode 120 and a respective support insulating layer 130 disposed on the same layer may be the same as the length in the second direction D2 of the mold insulating layer 110 disposed on another layer.

Each gate electrode 120 of the plurality of gate electrodes 120 has a longer length in the second direction D2 as the gate electrode is positioned farther away from the cell substrate 100, and therefore, each support insulating layer 130 of the plurality of support insulating layers 130 may have a shorter length in the second direction D2 thana support insulating layer is positioned farther away from the cell substrate 100. For example, a first support insulating layer 130 of the plurality of support insulating layers 130 may have a longer length in the second direction D2 than a second support insulating layer 130 closer to the first surface MS_1 of the mold structure MS, and a shorter length in the second direction D2 than a third support insulating layer 130 closer to the second surface MS_2 of the mold structure MS.

An interlayer insulating film 125 may be formed on the second surface MS 2 of the mold structure MS. The interlayer insulating film 125 may be disposed on the mold structure MS and cover the mold structure MS. The interlayer insulating film 125 may include silicon oxide, silicon oxynitride, or a low-k material having a dielectric constant lower than that of silicon oxide, but aspects are not limited thereto.

The channel structure CH may be disposed on the cell array region CAR of the cell substrate 100. The channel structure CH may extend in the first direction D1, that is, in a direction perpendicular to the first surface 100_A of the cell substrate 100. The channel structure CH may penetrate through the mold structure MS. The channel structure CH may penetrate through and intersect each gate electrode 120 of the plurality of gate electrodes 120. The channel structure CH may have a pillar shape (e.g., a cylindrical shape) extending lengthwise in the first direction D1. The first direction D1 may be a lengthwise direction for the channel structure. In some aspects, the cross section of the channel structure CH may have an inclined side surface such that its width is progressively narrowed toward the cell substrate 100. However, aspects are not limited thereto.

The channel structure CH may include a filling insulating layer, a semiconductor pattern, and an information storage film.

The semiconductor pattern may extend in the first direction D1 through the mold structure MS. It is illustrated that the semiconductor pattern has a cup shape, but aspects are not limited thereto. For example, the semiconductor pattern may have various shapes such as a cylindrical shape, a rectangular cylindrical shape, a filled pillar shape, etc. The semiconductor pattern may include a semiconductor material such as a single crystal silicon, a polycrystalline silicon, an organic semiconductor material, a carbon nanostructure, etc., but aspects are not limited thereto.

The information storage film may be interposed between the semiconductor pattern and each of the gate electrodes 120. For example, the information storage film may extend along an outer surface of the semiconductor pattern (e.g., extend laterally around the semiconductor pattern and extend the length of the semiconductor pattern in the first direction). The information storage film may include silicon oxide, silicon nitride, silicon oxynitride, or a high-k material having a higher dielectric constant than the silicon oxide. The high-k material may include aluminum oxide, hafnium oxide, lanthanum oxide, tantalum oxide, titanium oxide, lanthanum hafnium oxide, lanthanum aluminum oxide, dysprosium scandium oxide, or a combination thereof.

In some aspects, the channel structures CH may be arranged in a zigzag form as viewed in a cross section perpendicular to the first direction. For example, as illustrated in FIG. 1, the channel structures CH may be arranged with some of the channel structures CH overlapping other channel structures CH each other in the second direction D2 and a third direction D3. Having the channel structures CH disposed in the zigzag form may further improve the integration density of the semiconductor memory device. In some aspects, the channel structures CH may be arranged in a honeycomb form.

In some aspects, the information storage film may be formed of multiple films. The information storage film may include a tunnel insulating film, a charge storage film, and a blocking insulating film, which are sequentially stacked on the outer surface of the semiconductor pattern.

The tunnel insulating film may include the silicon oxide or a high-k material (e.g., aluminum oxide (Al₂O₃), hafnium oxide (HfO₂)) having a higher dielectric constant than the silicon oxide. The charge storage film may include silicon nitride. The blocking insulating film may include the silicon oxide or a high-k material (e.g., aluminum oxide (Al₂O₃) or hafnium oxide (HfO₂)) having a higher dielectric constant than the silicon oxide.

In some aspects, the channel structure CH may further include a filling insulating layer. The filling insulating layer may be formed to fill the inside of the cup-shaped semiconductor pattern. The filling insulating layer may include an insulating material such as silicon oxide, but aspects are not limited thereto.

In some aspects, a channel pad 132 may be disposed on the channel structure CH. The channel pad 132 may be formed to be connected to the semiconductor pattern. For example, the channel pad 132 may be provided in the interlayer insulating film 125 to be connected to one end of the semiconductor pattern. The channel pad 132 may include polysilicon doped with an impurity, but aspects are not limited thereto.

The word line cutting structure WCS may separate the mold structure MS at a spacing in the third direction D3 in the cell array region CAR. The word line cutting structure WCS may separate the plurality of gate electrodes 120 at a spacing in the third direction D3 in the extension region EXT. The word line cutting structure WCS may extend in the second direction D2. For example, the mold structure MS may be divided by the word line cutting structures WCS to form a memory cell block (e.g., BLK of FIG. 1).

Referring to FIG. 3, the word line cutting structure WCS may have a stepped structure (e.g., a stepped shape) WCS_ST progressively decreasing in length in the first direction D1. The stepped structure WCS_ST may be formed as a result of different parts of the word line cutting structure WCS having different depths, and with this stepped structure WCS_ST, the word line cutting structure WCS may have a plurality of steps. For example, in FIG. 3, lower ends of the word line cutting structure WCS may be positioned at different heights (i.e., at different vertical levels). Specifically, the stepped structure WCS_ST may have a plurality of steps that are differences in the length in the first direction DI formed between the adjacent lower ends of the word line cutting structure WCS.

The length of the word line cutting structure WCS in the first direction D1 may decrease in the extension region EXT at locations farther away from the cell array region CAR in the second direction D2. For example, the word line cutting structure WCS may have the stepped structure WCS_ST that decreases in length in the first direction D1 at positions farther away from the cell array region CAR in the second direction D2.

The stepped structure WCS_ST of the word line cutting structure WCS may have a plurality of steps along the second direction D2. Each of the plurality of steps of the stepped structure WCS_ST of the word line cutting structure WCS may have a predetermined height difference (e.g., a difference in position in the first direction D1). For example, each step of the stepped structure WCS_ST of the word line cutting structure WCS may correspond to a respective layer of the plurality of gate electrodes 120. For example, one layer of the gate electrodes 120 may be positioned in each step of the stepped structure WCS_ST of the word line cutting structure WCS. However, aspects are not limited thereto, and one or more layers of the plurality of gate electrodes 120 may be positioned in each step of the stepped structure WCS_ST.

A distance between the word line cutting structure WCS and the cell substrate 100 may be greater at locations farther away from the cell array region CAR along the second direction D2. The word line cutting structure WCS may be farther away from the cell substrate 100 at positions farther away from the cell array region CAR along the second direction D2. Conversely, the distance between the word line cutting structure WCS and the cell substrate 100 may be less at locations nearer to the cell array region CAR along the second direction D2. For example, referring to FIG. 3, the word line cutting structure WCS may have an inverted staircase shape (e.g., a staircase shape with the vertical direction inverted).

Referring to FIG. 1, when viewed in a plan view, a sidewall of the word line cutting structure WCS may include a plurality of curved surfaces WCS_S. The word line cutting structure WCS may include a plurality of holes WCS_H repeating in the second direction D2. The plurality of holes WCS_H may extend in the first direction D1. The plurality of holes WCS_H may have a cylindrical shape. The plurality of holes WCS_H may be disposed to overlap each other. As the plurality of holes WCS_H are disposed to overlap, a part of the cylindrical shape may be left in the sidewall of the word line cutting structure WCS to form the plurality of curved surfaces WCS_S. The word line cutting structure WCS may overlap the plurality of gate electrodes 120 in the third direction D3. In addition, a portion of the word line cutting structure WCS may not overlap the plurality of support insulating layers 130 in the third direction D3.

The word line cutting structure WCS may include an insulating material, for example, silicon oxide, silicon nitride, or silicon oxynitride, but aspects are not limited thereto.

The bit lines BL may be formed on the mold structure MS. The bit lines BL may intersect the word line cutting structure WCS. For example, each of the bit lines BL may extend in the third direction D3. The bit lines BL may be arranged at a spacing along the second direction D2.

The bit lines BL may be connected to the channel structures CH arranged along the third direction D3. A bit line contact 136 may be formed in the interlayer insulating film 125. The bit line BL may be electrically connected to the channel structure CH through the bit line contact 136 and the channel pad 132.

The word line contact 160 may be disposed on the extension region EXT of the cell substrate 100. The word line contact 160 may extend in the first direction D1 and be connected to the gate electrode 120. For example, the word line contact 160 may penetrate through a part of the mold structure MS and connect to the corresponding gate electrode 120.

A plurality of word line contacts 160 may be provided. The word line contacts 160 may extend in the first direction D1. The word line contacts 160 may extend along a stacking direction of the mold structure MS. Each of the word line contacts 160 may be penetrating through at least a part of the mold structure MS in the extension region EXT. The word line contacts 160 may penetrate through the second surface MS_2 of the mold structure MS. The word line contacts 160 may protrude from the second surface MS 2 of the mold structure MS in the first direction D1. Some of the word line contacts 160 may be disposed in the mold structure MS, and word line contacts 160 that are not disposed in the mold structure MS may be disposed outside the mold structure MS. The word line contacts 160 that are not disposed in the mold structure MS may protrude from the second surface MS_2 of the mold structure MS in the first direction D1.

The length of each word line contact 160 of the plurality of word line contacts 160 in the first direction D1 may decrease for word line contacts 160 positioned farther away from the cell array region CAR in the second direction D2. The length of each of the word line contacts of the plurality of word line contacts 160 in the first direction D1 may decrease for word line contacts 160 positioned farther away from the cell array region CAR. For example, the length in the first direction D1 of a word line contact, of the plurality of word line contacts 160, farther away from the cell array region CAR may be shorter than the length in the first direction D1 of a word line contact closer to the cell array region CAR.

The contact spacer 170 may be disposed on a side surface of the word line contact 160. The contact spacer 170 may extend in the first direction D1 along the side surface of the word line contact 160. The contact spacer 170 may surround the word line contact 160. The contact spacer 170 may include an insulating material. For example, the contact spacer 170 may include a silicon oxide-based insulating material.

The word line contact 160 and the contact spacer 170 may penetrate through a part of the mold structure MS. For example, the word line contact 160 and the contact spacer 170 may penetrate through one or more gate electrodes 120. The word line contact 160 and the contact spacer 170 may penetrate through one or more mold insulating layers 110.

A word line via 166 may be disposed on the word line contact 160. The word line via 166 may be disposed in the interlayer insulating film 125. The word line contact 160 may be electrically connected to the cell wiring structure 180 through the word line via 166.

The support column 150 may be disposed on the extension region EXT of the cell substrate 100. A plurality of support columns 150 may be provided. The support columns 150 may penetrate through at least a part of the mold structure MS. The support columns 150 may extend in the first direction D1. The support columns 150 may be disposed around the word line contacts 160. For example, four support columns 150 may be arranged around one word line contact 160. However, aspects are not limited thereto. For example, three support columns 150 may be arranged around one word line contact 160. The support columns 150 may support the mold structure MS or the word line contact 160 to prevent the mold structure MS or the word line contact 160 from collapsing or falling.

The support column 150 may include an insulating material. For example, the support column 150 may include a silicon oxide-based insulating material. However, aspects are not limited thereto.

The support column 150 may extend in the first direction D1. The support column 150 may extend in the stacking direction of the mold structure MS. Each of the support columns 150 may penetrate through at least a part of the mold structure MS in the extension region EXT. The support column 150 may penetrate through the second surface MS_2 of the mold structure MS. The support column 150 may protrude from the second surface MS_2 of the mold structure MS in the first direction D1. Some of the support columns 150 may be disposed in the mold structure MS, and support columns 150 not disposed in the mold structure MS may be disposed outside the mold structure MS. The support columns 150 not disposed in the mold structure MS may protrude from the second surface MS_2 of the mold structure MS in the first direction D1.

The length of each support column 150 of a plurality of support columns 150 in the first direction D1 may decrease for a support column 150 positioned farther away from the cell array region CAR in the second direction D2. The length of each support column of the plurality of support columns 150 in the first direction D1 may be less for a support column positioned farther away from the cell array region CAR. For example, the length in the first direction D1 of a support column, of the plurality of support columns 150, located farther away from the cell array region CAR may be shorter than the length in the first direction D1 of a support column located closer to the cell array region CAR.

The word line contacts 160 and the support columns 150 may be alternately disposed in the second direction D2. The word line contacts 160 and the support columns 150 may be arranged so as not to overlap each other based on the second direction D2. In addition, the word line contacts 160 and the support columns 150 may be alternately arranged in the third direction D3. The word line contacts 160 and the support columns 150 may be arranged so as not to overlap each other based on the third direction D3. The word line contacts 160 and the support columns 150 may be disposed in a zigzag form. The plurality of word line contacts 160 may be disposed at a predetermined spacing along the second direction D2. The plurality of support columns 150 may be arranged at a predetermined spacing along the second direction D2, and may not overlap the plurality of word line contacts 160 in the second and third directions D2 and D3.

Referring to FIG. 4, the plurality of word line contacts 160 may include a first word line contact 161 and a second word line contact 162 positioned at the same distance from the cell array region CAR in the second direction D2. The length of the first word line contact 161 extending in the first direction DI and the length of the second word line contact 162 extending in the first direction DI may be different from each other. The first word line contact 161 and the second word line contact 162 are only examples, and may refer to a word line contact overlapping in the third direction D3.

The plurality of gate electrodes 120 may include a first gate electrode 121 and a second gate electrode 122 disposed at different vertical levels. The first word line contact 161 and the second word line contact 162 may be connected to different gate electrodes. For example, the first word line contact 161 may be connected to the first gate electrode 121, and the second word line contact 162 may be connected to the second gate electrode 122. The first gate electrode 121 may refer to a gate electrode connected to the first word line contact 161, and the second gate electrode 122 may refer to a gate electrode connected to the second word line contact 162.

The length of a word line contact of the plurality of word line contacts 160 in the first direction D1 may be shorter than the length of the word line cutting structure WCS in the first direction D1 that overlaps the word line contact of the plurality of word line contacts 160 in the third direction D3. For example, the length of the first word line contact 161 in the first direction D1 may be shorter than the length of a part of the word line cutting structure WCS in the first direction that overlaps the first word line contact 161 in the third direction D3.

Referring to FIG. 5, the plurality of word line contacts 160 may include a third word line contact 163 and a fourth word line contact 164 positioned at the same distance from the cell array region CAR in the second direction D2. The third word line contact 163 and the fourth word line contact 164 may be positioned farther away from the cell array region CAR in the second direction D2 compared to the first word line contact 161 and the second word line contact 162. Accordingly, the length of the third word line contact 163 extending in the first direction D1 may be shorter than the length of the first word line contact 161 extending in the first direction D1. In addition, the length of the fourth word line contact 164 extending in the first direction D1 may be shorter than the length of the second word line contact 162 extending in the first direction D1. The length of the third word line contact 163 extending in the first direction DI and the length of the fourth word line contact 164 extending in the first direction DI may be different from each other.

The plurality of gate electrodes 120 may include a third gate electrode 123 and a fourth gate electrode 124 disposed at different vertical levels. The third word line contact 163 and the fourth word line contact 164 may be connected to different gate electrodes. The third word line contact 163 may be connected to the third gate electrode 123, and the fourth word line contact 164 may be connected to the fourth gate electrode 124. The third gate electrode 123 may refer to a gate electrode connected to the third word line contact 163, and the fourth gate electrode 124 may refer to a gate electrode connected to the fourth word line contact 164.

Further, as shown in FIG. 5, the length of the third word line contact 163 in the first direction D1 may be shorter than a part of the word line cutting structure WCS that overlaps the third word line contact 163 in the third direction D3.

Hereinbelow, length relations between the word line cutting structure WCS and the plurality of support columns 150 will be described. Description of a first support column 151, the first gate electrode 121, and a first support insulating layer 131 may be equally applicable to a plurality of support columns 150, a plurality of gate electrodes 120, a plurality of support insulating layers 130.

One end of the first word line contact 161 may be disposed in the first gate electrode 121. That is, the first word line contact 161 may penetrate through a part of the first gate electrode 121. However, aspects are not limited thereto, and one end of the first word line contact 161 may be in contact on the first gate electrode 121. The first word line contact 161 may penetrate through the gate electrodes between the first gate electrode 121 and the bit line BL in the first direction D1. The first gate electrode 121 may be a gate electrode at the deepest position among the gate electrodes through which the first word line contact 161 is formed.

The support insulating layers may be disposed on and adjacent to one surface (e.g., lower surface) of the first gate electrode 121. The support insulating layer closest to the first gate electrode 121 in the first direction D1 may be referred to as the first support insulating layer 131. At least one of the plurality of support columns 150 may be in contact with the first support insulating layer 131 (a first support column 150 may be in contact with a corresponding first support insulating layer 131). The support column, of the plurality of support columns 150, that is in contact with the first support insulating layer 131 may be referred to as the first support column 151.

One end of the first support column 151 may be disposed in the first support insulating layer 131. However, aspects are not limited thereto, and one end of the first support column 151 may be in contact on the first support insulating layer 131. The first support column 151 may penetrate through the first support insulating layer 131 and contact a support insulating layer at a deeper position. That is, the first support column 151 may be in contact with at least one insulating layer of the plurality of support insulating layers 130.

The word line cutting structure WCS may penetrate through the first gate electrode 121. The word line cutting structure WCS may not penetrate through the first support insulating layer 131. For example, one end of the word line cutting structure WCS may be positioned in the mold insulating layer 110 disposed between the first gate electrode 121 and the first support insulating layer 131. A first end of the first support column 151 may be disposed in the first support insulating layer 131, and a second end of the word line cutting structure WCS may be disposed in the mold insulating layer 110. One end of the word line cutting structure WCS may be disposed in the plurality of support insulating layers 130.

As such, the length of one of the plurality of support columns 150 in the first direction D1 may be longer than the length of the word line cutting structure WCS in the first direction D1 that overlaps the one of the plurality of support columns 150 in the third direction D3. For example, the length of the first word line contact 161 in the first direction D1 may be shorter than a part of the word line cutting structure WCS that overlaps the first word line contact 161 in the third direction D3.

The cell wiring structure 180 may be formed on the mold structure MS. For example, a first wiring insulating film 182 may be formed on the interlayer insulating film 125, and the cell wiring structure 180 may be formed in the first wiring insulating film 182. The cell wiring structure 180 may be electrically connected to the bit line BL and the word line contact 160. Accordingly, the cell wiring structure 180 may be electrically connected to the channel structure CH and the gate electrode 120. The number, arrangement, etc. of the layers of the illustrated cell wiring structure 180 are merely illustrative, and aspects are not limited thereto.

The peripheral circuit structure PERI may include a peripheral circuit substrate 300, a peripheral circuit element 360, and a peripheral circuit wiring structure 380.

The peripheral circuit substrate 300 may include a semiconductor substrate such as a silicon substrate, a germanium substrate, or a silicon-germanium substrate. Alternatively, the peripheral circuit substrate 300 may also include a silicon-on-insulator (SOI) substrate, a germanium-on-insulator (GOI) substrate, etc.

The peripheral circuit element 360 may be formed on the peripheral circuit substrate 300. The peripheral circuit element 360 may form a peripheral circuit that controls an operation of the semiconductor memory device. For example, the peripheral circuit element 360 may include a logic circuit 1130, a page buffer 1120, a decoder circuit 1110, etc. as shown in FIG. 18. In the following description, the surface of the peripheral circuit substrate 300 on which the peripheral circuit element 360 is disposed may be referred to as a front side of the peripheral circuit substrate 300. Conversely, the surface of the peripheral circuit substrate 300 opposite the front side of the peripheral circuit substrate 300 may be referred to as a back side of the peripheral circuit substrate 300.

The peripheral circuit element 360 may include a transistor, but aspects are not limited thereto. For example, the peripheral circuit element 360 may include not only various active elements such as transistors, etc., but also various passive elements such as capacitors, resistors, inductors, etc.

The peripheral circuit wiring structure 380 may be formed on the peripheral circuit element 360. For example, a second wiring insulating film 340 may be formed on the front side of the peripheral circuit substrate 300, and the peripheral circuit wiring structure 380 may be formed in the second wiring insulating film 340. The peripheral circuit wiring structure 380 may be electrically connected to the peripheral circuit element 360. The number, arrangement, etc. of the layers of the peripheral circuit wiring structure 380 illustrated herein are merely examples, and aspects are not limited thereto.

In some aspects, the cell structure CELL may be stacked on the peripheral circuit structure PERI. For example, the cell structure CELL may be stacked on the second wiring insulating film 340.

In some aspects, the second surface 100_B of the cell substrate 100 may face the peripheral circuit structure PERI. For example, the first surface 100_A of the cell substrate 100 may face the front side of the peripheral circuit substrate 300.

Hereinbelow, a semiconductor device according to another aspect will be described. The of elements that are the same as those already described above will be given the same reference numerals given previously and detailed description thereof may be omitted when such description may be redundant, the below description will be mainly with reference to differences from the aspects described above.

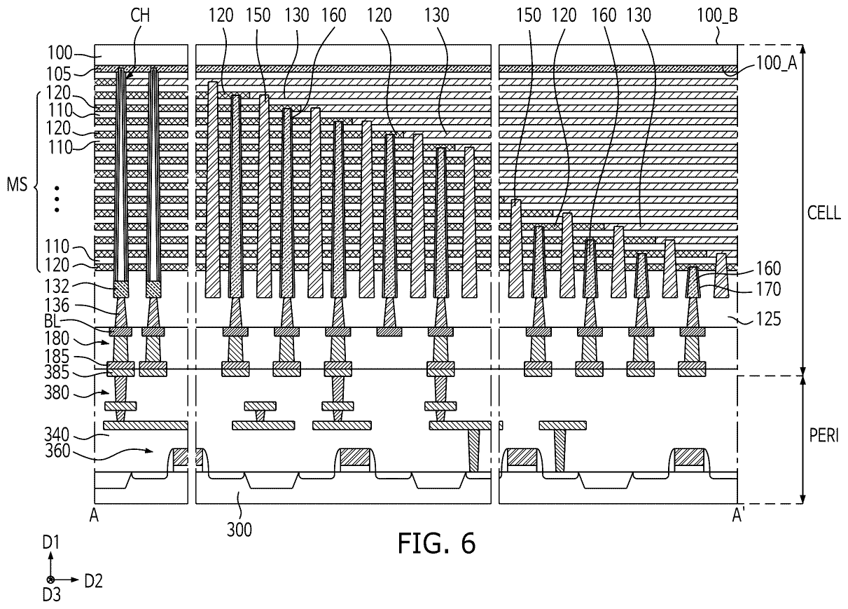

FIGS. 6 to 8 are diagrams provided to explain a semiconductor device according to some aspects.

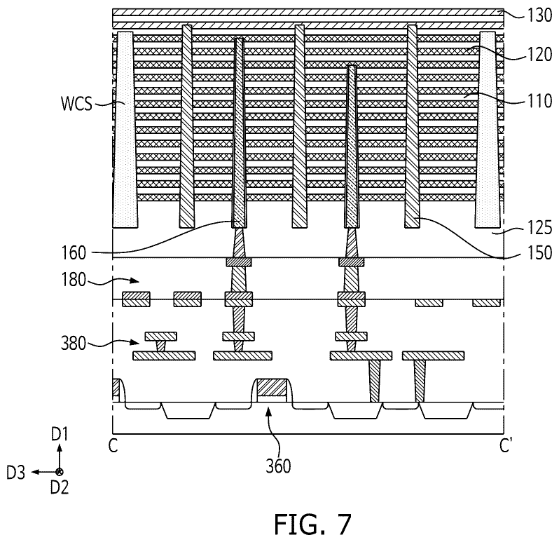

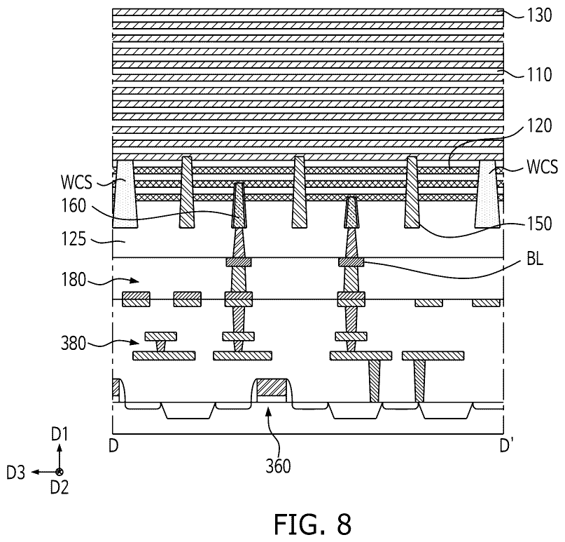

FIG. 6 may be a view corresponding to a cross-sectional view taken along line A-A′ of FIG. 1. FIG. 7 may be a view corresponding to a cross-sectional view taken along line C-C′ of FIG. 1. FIG. 8 may be a view corresponding to a cross-sectional view taken along line D-D′ of FIG. 1.

Referring to FIGS. 6 to 8, a semiconductor memory device according to some aspects may include a cell structure CELL and a peripheral circuit structure PERI.

The cell structure CELL may be disposed above the peripheral circuit structure PERI. Description of the peripheral circuit structure PERI may be the same as the above description with reference to FIGS. 1 to 5.

The cell structure CELL may include the cell substrate 100, the mold structure MS, the common source plate 105, the channel structure CH, the bit line BL, the support column 150, the word line contact 160, the contact spacer 170, etc.

The cell substrate 100 may include a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate, etc. In some aspects, the cell substrate 100 may include polysilicon (poly Si).

The cell substrate 100 may include a first surface 100_A and a second surface 100 B opposite to the first surface 100_A. The first surface 100_A of the cell substrate 100 may refer to a surface on which the mold structure MS and the channel structure CH are disposed. The first surface 100_A of the cell substrate 100 may refer to a lower surface of the cell substrate 100, and the second surface 100_B of the cell substrate 100 may refer to an upper surface of the cell substrate 100.

The common source plate 105 may be formed on the first surface 100_A of the cell substrate 100. The common source plate 105 may be disposed on the cell array region CAR, the extended region EXT, and the through region THR. The common source plate 105 may be connected to the channel structure CH. For example, the common source plate 105 may be electrically connected to the semiconductor pattern of the channel structure CH. The common source plate 105 may be connected to the source contact 184 in the through region THR. The common source plate 105 may be provided as a common source line (e.g., CSL of FIG. 18) of the semiconductor memory device. The common source plate 105 may include polycrystalline silicon or metal doped with impurities, but aspects are not limited thereto.

The mold structure MS may be disposed on the common source plate 105. The mold structure MS may be disposed on the cell array region CAR and the extension region EXT of the cell substrate 100. In addition, as described above with respect to FIGS. 1 to 5, the channel structure CH, the support column 150, the word line contact 160, etc. may be disposed in and through the mold structure MS. Further, the bit line BL may be disposed on the mold structure MS.

The semiconductor memory device according to some aspects may have a chip-to-chip (C2C) structure. The C2C structure refers to manufacturing an upper chip including the cell structure (CELL) on a first wafer (e.g., the cell substrate 100), manufacturing a lower chip including the peripheral circuit structure (PERI) on the second wafer (e.g., the peripheral circuit substrate 300) that is different from the first wafer, and connecting the upper and lower chips to each other by a bonding method.

In some aspects, bonding method may be a method of electrically connecting a first bonding metal 185 formed on the lowermost metal layer of the upper chip and a second bonding metal 385 formed on the uppermost metal layer of the lower chip to each other. For example, if the first bonding metal 185 and the second bonding metal 385 are formed of copper (Cu), the bonding method may be a Cu—Cu bonding method. However, this is only an example, the first bonding metal 185 and the second bonding metal 385 may be formed of various other metals such as aluminum (Al) or tungsten (W).

Because the first bonding metal 185 and the second bonding metal 385 are bonded to each other, the cell wiring structure 180 may be connected to the peripheral circuit wiring structure 380. Accordingly, the bit line BL and/or each of the gate electrodes 120 may be electrically connected to the peripheral circuit element 360.

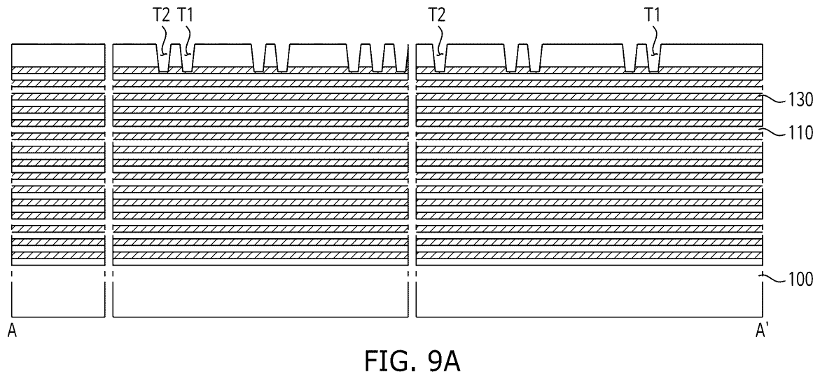

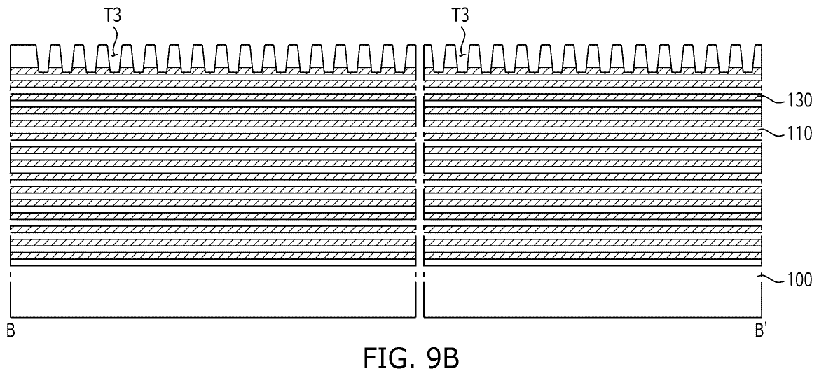

FIGS. 9A to 17B are diagrams showing intermediate stages, provided to explain a method for manufacturing a semiconductor device according to some aspects. FIGS. 9A, 10A, 11A, 12A, 13A, 14A, 16A, and 17A may correspond to a cross section taken along line A-A′ of FIG. 1, and FIGS. 9B, 10B, 11B, 12B, 13B, 15, 16B, and 17B may correspond to a cross section taken along line B-B′ of FIG. 1.

Referring to FIGS. 9A and 9B, a pre-stack structure PMS may be formed on the cell substrate 100. The pre-stack structure PMS may include an alternating stack of plurality of mold insulating layers 110 and sacrificial insulating layers 130. The peripheral circuit structure PERI may be disposed on a lower side of the cell substrate 100, but this is omitted in FIGS. 9A to 17B for convenience of explanation.

Etching may be performed on an upper side of the pre-stack structure PMS. An etching procedure for stacking the pre-stack structure PMS may include cyclic etching. This is only an example, and the semiconductor device may be manufactured by various etching procedures.

In a first cyclic etching, 0 to the power of 2, that is, one sacrificial insulating layer 130 of the pre-stack structure PMS may be etched. A first trench T1, a second trench T2, and a third trench T3 may be formed on the pre-stack structure PMS. The first trench T1, the second trench T2, and the third trench T3 may be provided to form the word line contact, the support column, and the word line cutting structure, respectively. The first trench T1, the second trench T2, and the third trench T3 may penetrate through one layer of sacrificial insulating layer 130.

The first trench T1 and the second trench T2 may be formed in a region that will become the cell block BLK (FIG. 1) of the pre-stack structure PMS, and the third trench T3 may be formed in a region that will become the word line cutting structure WCS (FIG. 1) of the pre-stack structure PMS.

The first trench T1, the second trench T2, and the third trench T3 may penetrate through a part of the pre-stack structure PMS. Bottom surfaces of the first trench T1 and the second trench T2 may expose the sacrificial insulating layer 130. However, aspects are not limited thereto. For example, the bottom surfaces of the first trench T1 and the second trench T2 may expose the mold insulating layer 110.

The first trench T1 and the second trench T2 may be formed at a predetermined spacing. The first trench T1 and the second trench T2 may be alternately disposed in the second direction D2 (e.g., there may be multiple first trenches T1 and multiple second trenches T2 and they may alternate between a first trench T1 and a second trench T2 in the second direction D2). The first trench T1 and the second trench T2 may be alternately disposed in the third direction D3 (e.g., the trenches may alternate between a first trench T1 and a second trench T2 in the third direction D3). The first trench T1 and the second trench T2 may be disposed so as not to overlap each other with respect to the third direction D3. The first trench T1 and the second trench T2 may be disposed in a zigzag form. A plurality of first trenches Tl may be disposed at a predetermined spacing in the second direction D2. A plurality of second trenches T2 may be disposed at a predetermined spacing in the second direction D2, and may be disposed so as not to overlap the plurality of first trenches T1 in the second and third directions D2 and D3.

The third trenches T3 may be formed at a smaller spacing than the first trenches T1. In addition, the third trenches T3 may be formed at a smaller spacing than the second trenches T2.

The first trench T1, the second trench T2, and the third trench T3 may have a tapered shape that progressively decreases in width as they approach the cell substrate 100. However, aspects are not limited thereto. For example, each of the first trench T1, the second trench T2, and the third trench T3 may have a constant width.

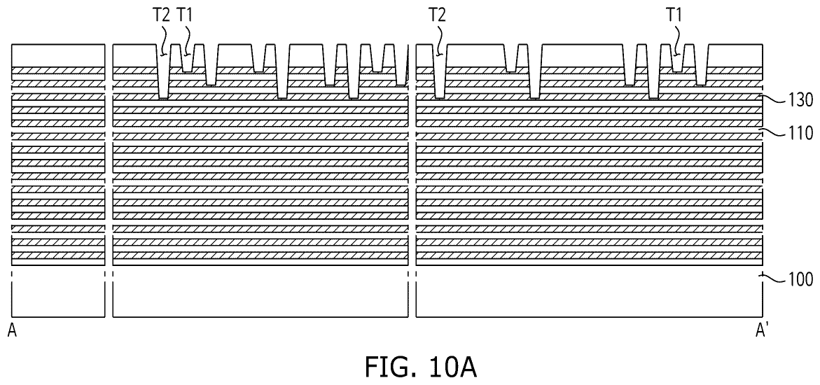

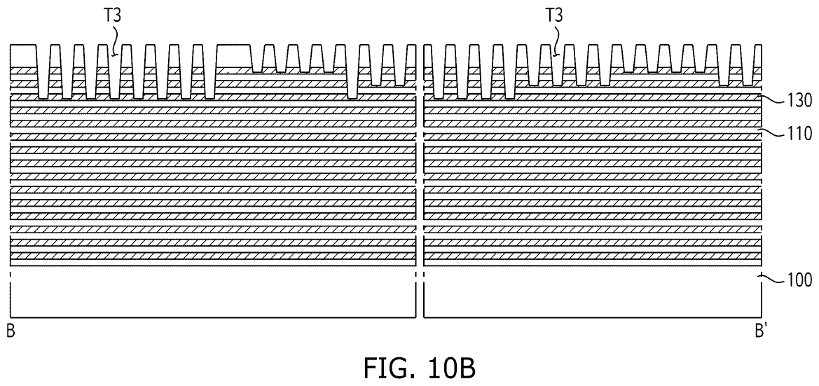

Referring to FIGS. 10A and 10B, a second cyclic etching may be performed. In the second cyclic etching, 1 to the power of 2, that is, two sacrificial insulating layers 130 of the pre-stack structure PMS may be etched.

The second cyclic etching may be performed on the first trench T1, the second trench T2, and the third trench T3 formed in the first cyclic etching. That is, depths of the first trench T1, the second trench T2, and the third trench T3 may further increase. Specifically, the depths of the first trench T1, the second trench T2, and the third trench T3 may extend to the third sacrificial insulating layer 130.

In the second cyclic etching, etching may be performed in a region where the first trench T1, the second trench T2, and the third trench T3 are not formed. In this case, the depth of each of the first trench T1, the second trench T2, and the third trench T3 may extend to the second sacrificial insulating layer 130.

In the second cyclic etching, there may be no etching performed on a first trench T1, a second trench T2, or a third trench T3 such that a trench in which no etching is performed in the second cyclic etching penetrates through the first sacrificial insulating layer 130 but does not extend into the second sacrificial insulating layer 130.

After the second cyclic etching is complete, each of the first, second, and third trenches T1, T2, and T3 may penetrate through one, two, or three sacrificial insulating layers 130 depending on during which cyclic etching the trench was etched.

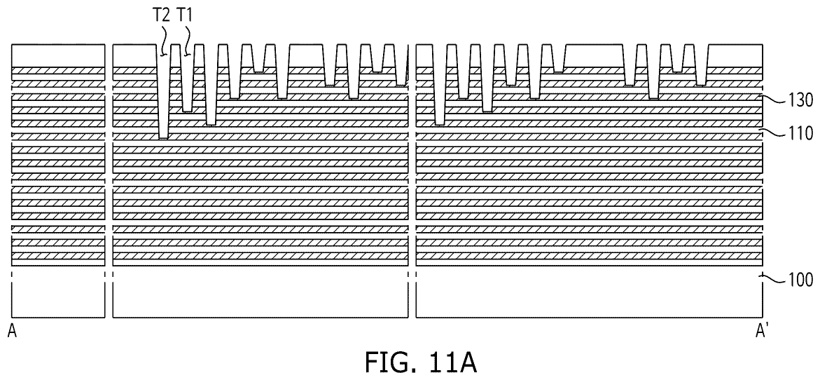

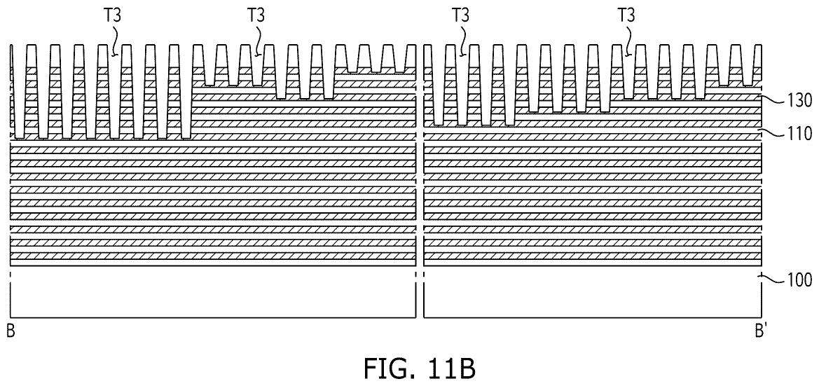

Referring to FIGS. 11A and 11B, a third cyclic etching may be performed. In the third cyclic etching, 2 to the power of 2, that is, four sacrificial insulating layers 130 of the pre-stack structure PMS may be etched.

The third cyclic etching may be performed on a region left unetched in both the first cyclic etching and the second cyclic etching. The depths of the first trench T1, the second trench T2, and the third trench T3 formed only by the third cyclic etching may extend to the fourth sacrificial insulating layer 130.

The third cyclic etching may be performed on the first trench T1, the second trench T2, and the third trench T3 formed only by the first cyclic etching (and not etched in the second cyclic etching). As a result, each of the first trench T1, the second trench T2, and the third trench T3 formed only by the first cyclic etching may penetrate through five layers of sacrificial insulating layers 130.

In addition, the third cyclic etching may be performed on the first trench T1, the second trench T2, and the third trench T3 formed only by the second cyclic etching (and not etched in the first cyclic etching). In this case, each of the first trench T1, the second trench T2, and the third trench T3 may penetrate through six layers of sacrificial insulating layers 130.

The third cyclic etching may be performed on the first trench T1, the second trench T2, and the third trench T3 formed by etching in both the first and second cyclic etching. In this case, each of the first trench T1, the second trench T2, and the third trench T3 may penetrate through seven layers of sacrificial insulating layers 130.

As such, after the third cyclic etching is complete, each of the first trench T1, the second trench T2, and the third trench T3 may penetrate through the depth of any of one to seven layers of sacrificial insulating layer 130.

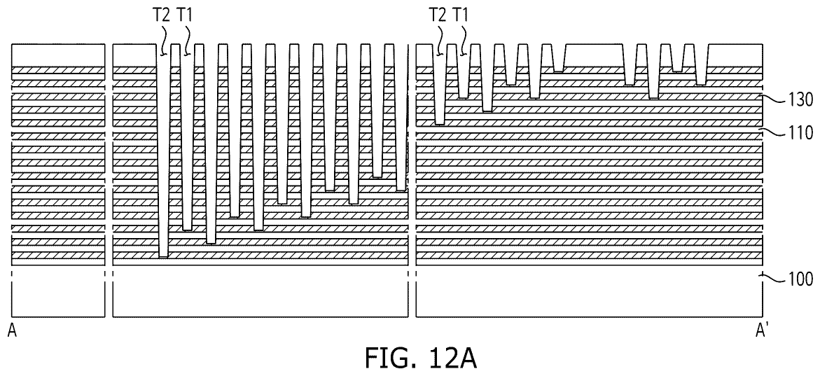

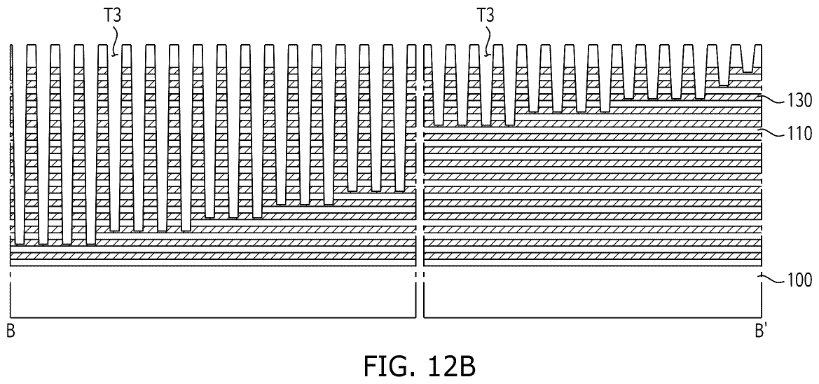

Referring to FIGS. 12A and 12B, a fourth cyclic etching may be performed. In the fourth cyclic etching, 3 to the power of 2, that is, eight sacrificial insulating layers 130 of the pre-stack structure PMS may be etched.

After the fourth cyclic etching is complete through the same process as described above with respect to the first to third cyclic etching, each of the first trench T1, the second trench T2, and the third trench T3 may penetrate through a depth of any of one to fifteen layers of sacrificial insulating layers 130.

Although not illustrated, if a fifth cyclic etching is performed, each of the first trench T1, the second trench T2, and the third trench T3 may penetrate through one to thirty one layers of sacrificial insulating layers 130. For convenience of description, it is illustrated herein that the sacrificial insulating layers 130 of the pre-mold structure PMS are fifteen layers in total, but aspects are not limited thereto. As more cyclic etching is performed, the first, second, and third trenches T1, T2, and T3 may be formed deeper. The first trench T1, the second trench T2, and the third trench T3 may all be formed to have a shallower depth toward the direction of the second direction D2.

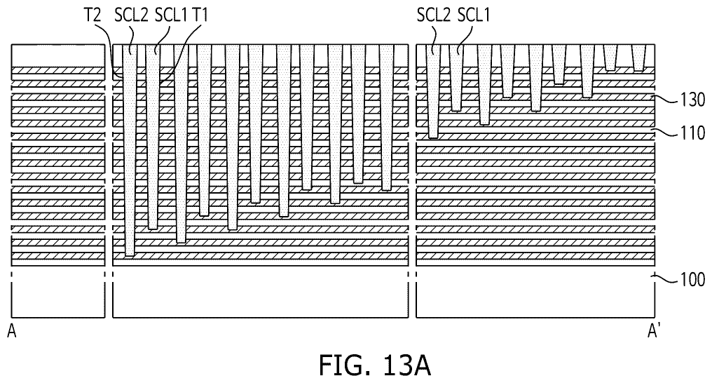

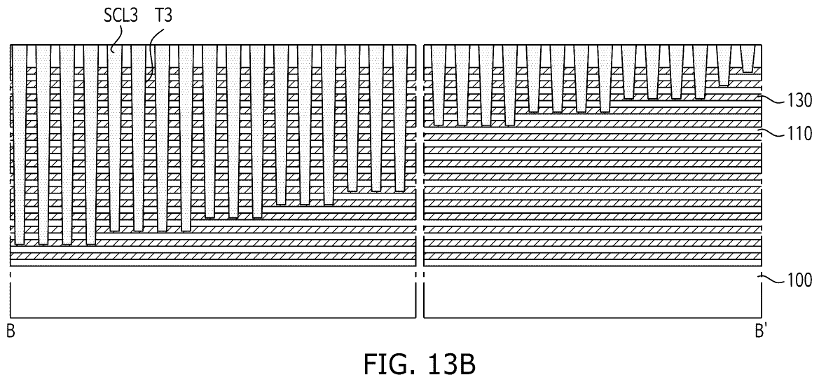

Referring to FIGS. 13A and 13B, a sacrificial layer SCL may fill the first trench T1, the second trench T2, and the third trench T3. The sacrificial layer SCL may be a material having selectivity to an oxide or silicon nitride (SiN), and may include any one of C, W, and TiN, for example. A first sacrificial layer SCL1, a second sacrificial layer SCL2, and a third sacrificial layer SCL3 may fill the first trench T1, the second trench T2, and the third trench T3, respectively. Specifically, the first sacrificial layer SCL1, the second sacrificial layer SCL2, and the third sacrificial layer SCL3 may fill each of the first, second, and third trenches T1, T2, and T3 that penetrate through any of one to fifteen layers of sacrificial insulating layers 130.

Referring to FIG. 14, the second sacrificial layer SCL2 (FIG. 13A) filling the second trench T2 may be removed. The second trench T2 may be filled with an insulating material. The support column 150 may be formed in the second trench T2. For example, a silicon oxide-based insulating material may be included in the second trench T2. The insulating material in the second trench T2 may be a material having selectivity to silicon nitride (SiN). However, aspects are not limited thereto.

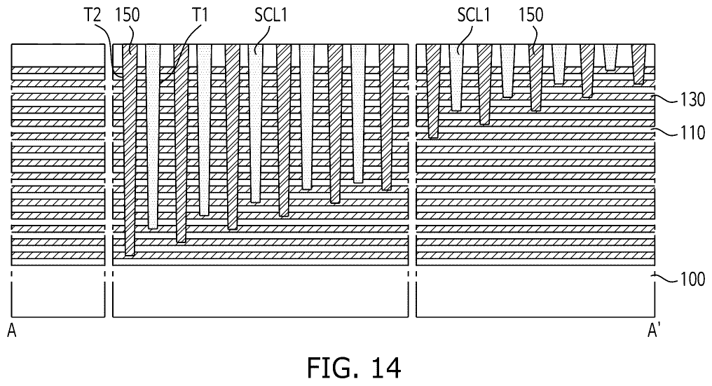

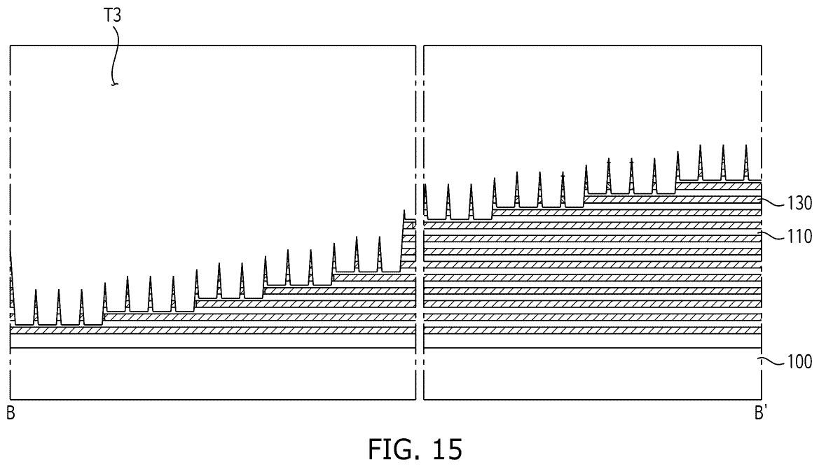

Referring to FIG. 15, the third sacrificial layer SCL3 (FIG. 13B) filling the third trench T3 may be removed. A cleaning process may be performed within the third trench T3 from which the third sacrificial layer SCL3 has been removed. For example, the cleaning process may be performed within the third trench T3 using an acidic material such as hydrofluoric acid (HF).

The size of the third trench T3 may increase due to the acidic material used in the cleaning process. As the size of the third trench T3 increases, the third trench T3 may overlap the adjacent third trench T3. Specifically, the third trenches T3 are spaced apart from each other at a predetermined spacing, but as the size of the third trenches T3 increases, the spacing between the third trenches T3 decreases until there is no space remaining and the third trenches T3 are joined. For example, the plurality of third trenches T3 may be integrally formed in communication with each other. In addition, by the cleaning process, the bottom surfaces between the adjacent third trenches T3 may be connected to each other and substantially planarized.

Further, the length of the third trench T3 in the first direction D1 may also increase. The third trench T3 may be formed completely through the sacrificial insulating layer 130 that the third trench T3 is in contact with at the end of the third trench T3. For example, the third trench T3 may penetrate through the sacrificial insulating layer 130 such that the end of the third trench T3 may be positioned in the mold insulating layer 110. In this example, the length of the third trench T3 in the first direction DI may be kept to be shorter than that of the second trench T2 in the first direction D1.

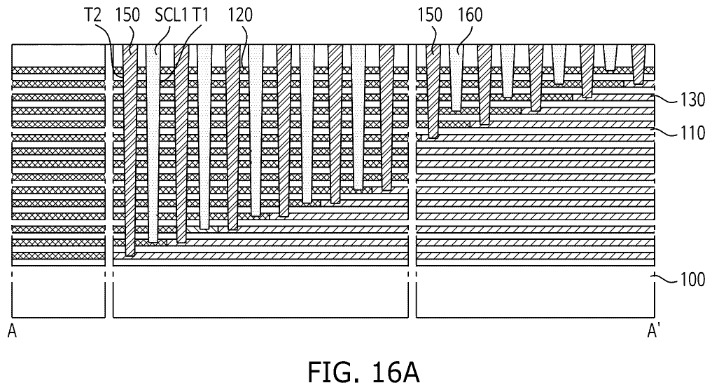

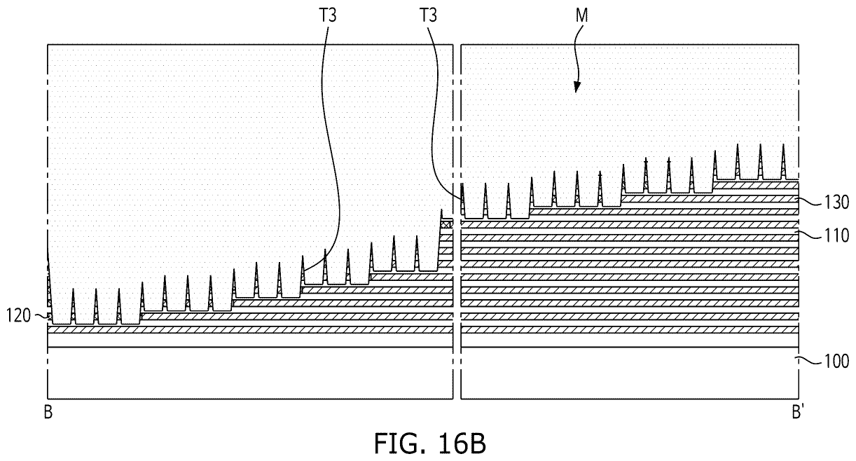

Referring to FIGS. 16A and 16B, a part of a plurality of sacrificial insulating layers 130 may be removed through the third trench T3. As the part of the plurality of sacrificial insulating layers 130 is removed, a space may be formed between the plurality of mold insulating layers 110. The remaining part of the sacrificial insulating layers 130 which is not removed may be used as the support insulating layer described previously.

A metal material M may be introduced through the inside of the third trench T3. The metal material M introduced through the third trench T3 may fill the space between the plurality of mold insulating layers 110. The metal material filling the space between the plurality of mold insulating layers 110 may form the plurality of gate electrodes 120. Further, the inside of the third trench T3 may be filled with the metal material.

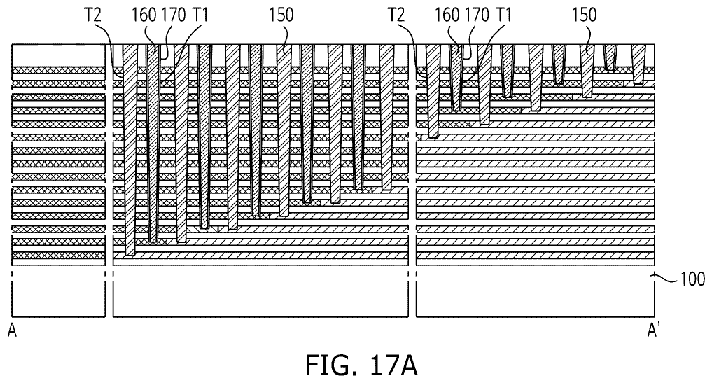

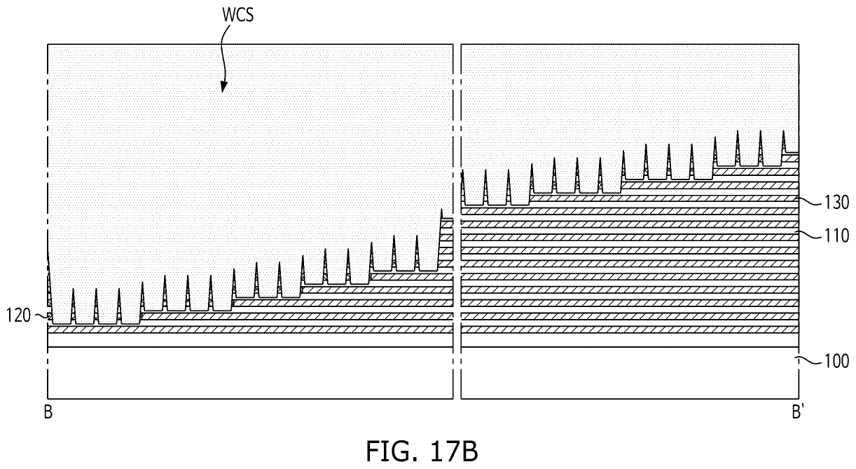

Referring to FIGS. 17A and 17B, the word line contact 160 and the contact spacer 170 may be formed in the first trench T1. To this end, the first sacrificial layer SCL1 (FIG. 16A) filling the first trench T1 may be removed. In addition, the contact spacer 170 may be formed along a sidewall and a bottom surface of the first trench T1. The contact spacer 170 may be conformally formed on the first trench T1. For example, the contact spacer 170 may be formed using any one of chemical vapor deposition (CVD), low pressure image vapor deposition (LP-CVD), plasma enhanced CVD (PE-CVD), and atomic layer deposition (ALD).

A bottom surface of the contact spacer 170 formed in the first trench T1 may be removed. The word line contact 160 may be formed by filling the first trench T1 with a metal material. Specifically, the metal material may fill between side surfaces of the contact spacer 170 formed in the first trench T1. That is, the metal material may be exposed through the bottom surface of the first trench T1.

The word line cutting structure WCS may be formed in the third trench T3. The word line cutting structure WCS may be formed by removing the metal material filling the third trench T3 and then filling the third trench T3 with an insulating material. For example, the insulating material for filling the third trench T3 may include silicon oxide, silicon nitride, or silicon oxynitride, but aspects are not limited thereto.

The semiconductor device of FIGS. 1 to 5 may be provided as the bit line BL, the bit line contact 136, the channel pad 132, etc. are formed on the mold structure MS.

FIG. 18 is a block diagram provided as an example to explain an electronic system according to some aspects.

Referring to FIG. 18, an electronic system 1000 may include the semiconductor device 1100 described above with reference to FIGS. 1 to 8 and a controller 1200 electrically connected to the semiconductor device 1100. The electronic system 1000 may be a storage device including one or a plurality of semiconductor devices 1100 or an electronic device including a storage device. For example, the electronic system 1000 may be a solid state drive device (SSD), a universal serial bus (USB), a computing system, a medical device, or a communication device including one or a plurality of semiconductor devices 1100.

For example, the semiconductor device 1100 may be the NAND flash memory device described above with reference to FIGS. 1 to 8. The semiconductor device 1100 may include a first structure 1100F and a second structure 1100S on the first structure 1100F. The first structure 1100F may be a peripheral circuit structure including a decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various aspects.

In example aspects, the upper transistors UT1 and UT2 may include a string select transistor, and the lower transistors LT1 and LT2 may include a ground select transistor.

The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some aspects, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to predetermined firmware, and may control the NAND controller 1220 to access the semiconductor device 1100. The NAND controller 1220 may include a NAND interface 1221 that processes communication with the semiconductor device 1100. A control command for controlling the semiconductor device 1100, data to be written in the memory cell transistors MCT of the semiconductor device 1100, data to be read from the memory cell transistors MCT of the semiconductor device 1100, etc. may be transmitted through the NAND interface 1221. The host interface 1230 may provide a function of communication between the electronic system 1000 and an external host. Upon receiving a control command from the external host through the host interface 1230, the processor 1210 may control the semiconductor device 1100 in response to the control command.

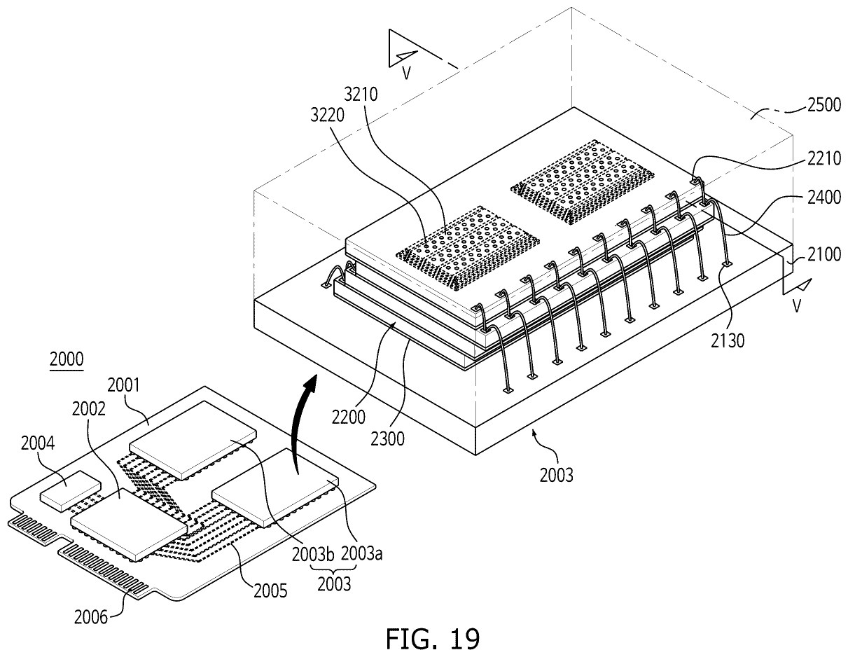

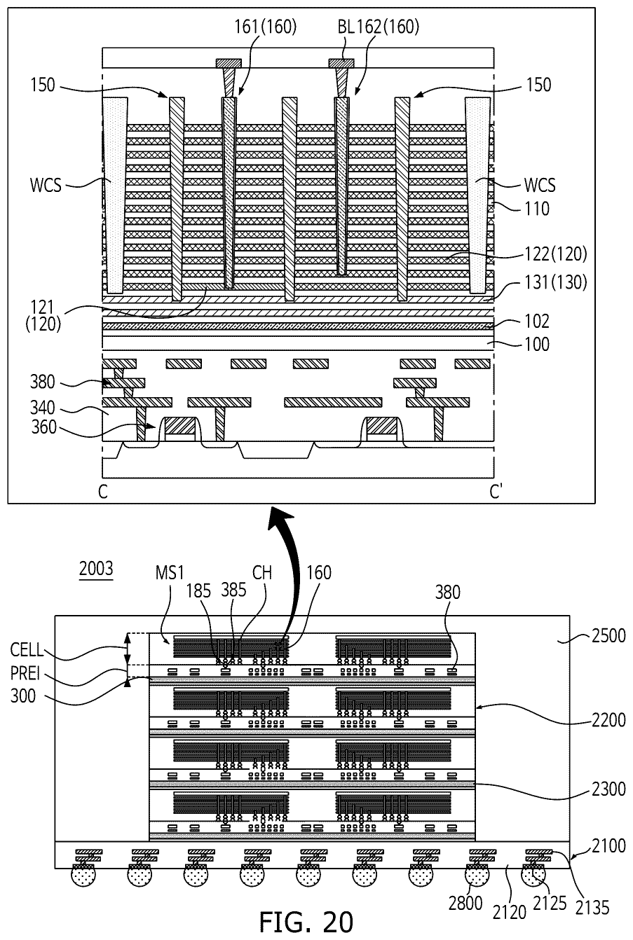

FIG. 19 is an example perspective view illustrating an electronic system including a semiconductor device according to some aspects. FIG. 20 is a schematic cross-sectional view taken along line V-V of FIG. 19.

Referring to FIGS. 19 and 20, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. In some aspects, the electronic system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some aspects, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit substrate including package upper pads 2130. Each of the semiconductor chips 2200 may include an input and output pad 2210. The input and output pad 2210 may correspond to the input and output pad 1101 of FIG. 18. Each of the semiconductor chips 2200 may include metal lines 3210 and channel structures 3220. Each of the semiconductor chips 2200 may include the semiconductor memory device described above with reference to FIGS. 1 to 8.

In some aspects, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some aspects, in each of the first and second semiconductor packages 2003a and 2003b, the semiconductor chips 2200 may be electrically connected to each other through a connection structure including through-electrodes (Through Silicon Via, TSV) instead of the bonding wire type connection structure 2400.

In some aspects, the main controller 2002 and the semiconductor chips 2200 may be included in one package. In some aspects, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some aspects, the package substrate 2100 may be a printed circuit substrate. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 19.

In an electronic system according to some aspects, each of the semiconductor chips 2200 may include the semiconductor memory device described above with reference to FIGS. 1 to 8. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 and the peripheral circuit wiring structure 380 described above with reference to FIGS. 1 to 8. Further, for example, the cell structure CELL may include the cell substrate 100, the mold structure MS, the channel structure CH, the bit line BL, the word line contact 160, and the contact spacer 170 described above with reference to FIGS. 1 to 8. The peripheral circuit structure PERI and the cell structure CELL may be bonded to each other through the first bonding metal 185 and the second bonding metal 385.

1. A semiconductor device, comprising:
a cell substrate including a cell array region and an extension region;
a mold structure including a plurality of mold insulating layers and a plurality of gate electrodes, wherein the mold insulating layers are alternately stacked with the gate electrodes on the cell substrate in a first direction perpendicular to an upper surface of the cell substrate, and the mold insulating layers and the gate electrodes extend lengthwise in a second direction parallel to the upper surface of the cell substrate;
a channel structure penetrating through the mold structure in the cell array region and extending lengthwise in the first direction;
a plurality of word line contacts, wherein each of the word line contacts is connected to a respective gate electrode of the plurality of gate electrodes; and
a word line cutting structure separating the mold structure in the cell array region in a third direction perpendicular to each of the first and second directions,
wherein the word line cutting structure has a stepped shape that decreases in length in the first direction in the extension region as the word line cutting structure extends away from the cell array region in the second direction.

2. The semiconductor device according to claim 1, wherein the length in the second direction of each of the plurality of gate electrodes that is positioned farther away from the cell substrate in the first direction than a first gate electrode is greater than the length of the first gate electrode, and
the length in the first direction of each of the plurality of word line contacts that is positioned farther away from the cell array region than a first word line contact is less than the length in the first direction of the first word line contact.

3. The semiconductor device according to claim 1, further comprising a plurality of support columns penetrating through at least a part of the mold structure and extending lengthwise in the first direction,
wherein the length in the first direction of each of the plurality of support columns that is farther away from the cell array region than a first support column of the plurality of support columns is less than the length in the first direction of the first support column.

4. The semiconductor device according to claim 3, wherein the word line contacts and the support columns are alternately disposed with one another in the second direction.

5. The semiconductor device according to claim 1, wherein the plurality of word line contacts comprises a first word line contact and a second word line contact which positioned at the same distance from the cell array region in the second direction, and
the length of the first word line contact extending lengthwise in the first direction is different than the length of the second word line contact extending lengthwise in the first direction.

6. The semiconductor device according to claim 5, wherein the plurality of gate electrodes comprises a first gate electrode and a second gate electrode which are disposed at different vertical levels than each other, and
the first word line contact is connected to the first gate electrode, and the second word line contact is connected to the second gate electrode.

7. The semiconductor device according to claim 1, wherein the mold structure further comprises a plurality of support insulating layers with each support insulating layer formed at the same vertical level as a corresponding gate electrode of the plurality of gate electrodes, and
the length in the second direction of each of the plurality of support insulating layers that is farther away from the cell substrate than a first support insulating layer of the plurality of support insulating layers is less than the length of the first support insulating layer.

8. The semiconductor device according to claim 7, further comprising a plurality of support columns penetrating through at least a part of the mold structure and extending lengthwise in the first direction,
wherein one end of each of the plurality of support columns is in contact with a corresponding support insulating layer of the plurality of support insulating layers.

9. The semiconductor device according to claim 8, wherein the length of a first word line contact of the plurality of word line contacts in the first direction is shorter than the length in the first direction of a support column of the plurality of support columns that is adjacent to the first word line contact.

10. The semiconductor device according to claim 1, wherein, in a plan view, a sidewall of the word line cutting structure comprises a plurality of curved surfaces.

11. The semiconductor device according to claim 1, wherein the length of a first word line contact of the plurality of word line contacts in the first direction is shorter than the length of the word line cutting structure in the first direction at a position where the word line cutting structure overlaps the first word line contact of the plurality of word line contacts in the third direction.

12. The semiconductor device according to claim 1, further comprising a plurality of support columns penetrating through at least a part of the mold structure and extending lengthwise in the first direction,
wherein the length of a first support column of the plurality of support columns in the first direction is longer than the length of the word line cutting structure in the first direction at a location that overlaps the first support column of the plurality of support columns in the third direction.

13. The semiconductor device according to claim 1, wherein an end of the word line cutting structure is disposed in the plurality of mold insulating layers.

14. The semiconductor device according to claim 1, wherein the mold structure includes a first surface facing the cell substrate and a second surface positioned opposite to the cell substrate, and
the plurality of word line contacts protrudes from the second surface of the mold structure in the first direction.

15. A semiconductor device, comprising:
a peripheral circuit structure; and
a cell structure stacked on the peripheral circuit structure,
wherein the cell structure comprises:
a cell substrate including a cell array region and an extension region;
a mold structure comprising a plurality of mold insulating layers and a plurality of gate electrodes, wherein the mold insulating layers are alternately stacked in a first direction perpendicular to an upper surface of the cell substrate with the gate electrodes on the cell substrate and the mold insulating layers extend lengthwise in a second direction parallel to the upper surface of the cell substrate, wherein the mold structure includes a plurality of support insulating layers with each support insulating layer of the plurality of support insulating layers formed at the same vertical level as a corresponding gate electrode of the plurality of gate electrodes;
a channel structure penetrating through the mold structure in the cell array region and extending lengthwise in the first direction; and
a plurality of word line contacts, wherein each of the word line contacts is connected to a corresponding gate electrode of the plurality of gate electrodes,
wherein the length in the second direction of each of the plurality of gate electrodes that are farther away from the cell substrate than a first gate electrode of the plurality of gate electrodes is less than the length in the second direction of the first gate electrode, and
the length in the second direction of each of the plurality of support insulating layers that are farther away from the cell substrate than a first support insulating layer of the plurality of support insulating layers is less than the length of the first support insulating layer in the first direction.

16. The semiconductor device according to claim 15, further comprising a plurality of support columns penetrating through the mold structure in the extension region and extending lengthwise in the first direction, wherein
the length in the first direction of each of the plurality of word line contacts that is farther away from the cell array region than a first word line contact of the plurality of word line contacts is less than the length in the first direction of the first word line contact, and
the length in the first direction of each of the plurality of support columns positioned farther away from the cell array region than a first support column of the plurality of support columns is less than the length in the first direction of the first support column.

17. The semiconductor device according to claim 16, wherein an end of each of the plurality of support columns is in contact with a corresponding support insulating layer of the plurality of support insulating layers.

18. The semiconductor device according to claim 16, further comprising a word line cutting structure that separates the mold structure in the cell array region in a third direction perpendicular to each of the first and second directions, wherein the word line cutting structure has a stepped structure that decreases in length in the first direction in the extension region at positions farther away from the cell array region in the second direction.

19. The semiconductor device according to claim 18, wherein the length of the word line cutting structure in the second direction increases at positions farther away from the cell substrate,
the length in the first direction of a second word line contact of the plurality of word line contacts is shorter than the length of the word line cutting structure in the first direction at a first position where the second word line contact overlaps the word line cutting structure in the third direction, and
the length in the first direction of a second support column of the plurality of support columns is longer than the length of the word line cutting structure in the first direction at a second position where the second support column overlaps the word line cutting structure in the third direction.

20. An electronic system, comprising:
a main substrate;
a semiconductor device on the main substrate, the semiconductor device comprising a peripheral circuit structure and a cell structure stacked on the peripheral circuit structure; and
a controller on the main substrate, the controller electrically connected to the semiconductor device,
wherein the cell structure comprises:
a cell substrate comprising a cell array region and an extension region;
a mold structure comprising a plurality of mold insulating layers and a plurality of gate electrodes, wherein the mold insulating layers are alternately stacked in a first direction perpendicular to an upper surface of the cell substrate the gate electrodes on the cell substrate, wherein the mold structure includes a first surface facing the cell substrate and a second surface positioned opposite to the cell substrate, the mold structure including a plurality of support insulating layers with each support insulating layer of the plurality of support insulating layers formed at the same vertical level as a corresponding gate electrode of the plurality of gate electrodes, wherein each of the plurality of gate electrodes extends in a second direction parallel to the upper surface of the cell substrate;
a channel structure penetrating through the mold structure in the cell array region and extending lengthwise in the first direction;
a plurality of support columns extending lengthwise in the first direction in the extension region, wherein some of the plurality of support columns are disposed in the mold structure and support columns that are not disposed in the mold structure protrude above the mold structure;
a plurality of word line contacts extending lengthwise in the first direction in the extension region, wherein some of the word line contacts are disposed in the mold structure, and word line contacts that are not disposed in the mold structure protrude from the second surface of the mold structure; and
a word line cutting structure penetrating through the mold structure in the first direction in the cell array region, and having a stepped shape decreasing in length in the first direction in the extension region at positions farther away from the cell array region in the second direction,
wherein the length in the second direction of each of the plurality of gate electrodes that is nearer to the second surface of the mold structure than a first gate electrode of the plurality of gate electrodes is greater than the length in the second direction of the first gate electrode, and
the length in the second direction of each of the plurality of support insulating layers that is nearer to the second surface of the mold structure than a first support insulating layer of the plurality of support insulating layers is less than the length in the second direction of the first support insulating layer.
